(19) United States
(12) Patent Application Publication
(10) Pub. No.: US 2026/0150652 A1
(43) Pub. Date: May 28, 2026

(54) SEMICONDUCTOR STRUCTURE AND METHOD OF MANUFACTURING THEREOF

(71) Applicant: AP MEMORY TECHNOLOGY CORPORATION, HSINCHU COUNTY (TW)

(72) Inventors: KEE-WEI CHUNG, HSINCHU COUNTY (TW); WEN-LIANG CHEN, HSINCHU COUNTY (TW); RU-YI CAI, HSINCHU COUNTY (TW)

(21) Appl. No.: 18/958,297

(22) Filed: Nov. 25, 2024

(51) Int. Cl. H01L 23/528; H01L 23/522; H01L 23/532

(52) U.S. Cl. CPC H10W 20/435; H10W 20/42; H10W 20/4403; H10W 20/496

(57) ABSTRACT

A semiconductor device includes a first stacking pair and a connecting unit. The first stacking pair comprises a first repeating unit and a second repeating unit. The first repeating unit comprises a first dielectric layer, a first device surrounded by the first dielectric layer, and a first interconnect structure comprising a first metal layer over the first device and surrounded by the first dielectric layer, the first metal layer electrically coupled to the first device. The second repeating unit comprises a second dielectric layer, a second interconnect structure comprising a second metal layer bonded to the first metal layer, and a second device surrounded by the second dielectric layer and electrically coupled to the second metal layer. The connecting unit comprises a contact pad electrically coupled to the first metal layer and the second metal layer. A method of manufacturing the semiconductor structure is also disclosed.

### TECHNICAL FIELD

The present disclosure relates to a semiconductor structure, and more particularly, to a bonded semiconductor structure.

### BACKGROUND

Currently, an increasing number of electronic products are adopting three-dimensional (3D) semiconductor bonding technology to enhance system performance, integration density, signal transmission speed, and data processing capacity. This technology includes chip-on-chip stacking, chip-on-wafer (CoW) stacking, and wafer-on-wafer (WoW) stacking. For example, wafer-on-wafer stacking allows for the vertical connections between of multiple wafers, achieving the vertical integration of multiple chips.

However, there are still many problems with existing semiconductor bonding or stacking structures. For example, a precise alignment of two semiconductor structures to be bonded is of great importance but usually difficult to achieve. Therefore, it is necessary to improve semiconductor manufacturing methods to form semiconductor structures with better electrical performance.

### SUMMARY

One aspect of the present disclosure provides a semiconductor structure. The semiconductor structure includes a first stacking pair and a connecting unit. The first stacking pair comprises a first repeating unit and a second repeating unit. The first repeating unit comprises a first dielectric layer, a first device surrounded by the first dielectric layer, and a first interconnect structure comprising a first metal layer over the first device and surrounded by the first dielectric layer, the first metal layer electrically coupled to the first device. The second repeating unit comprises a second dielectric layer, a second interconnect structure comprising a second metal layer bonded to the first metal layer, and a second device surrounded by the second dielectric layer and electrically coupled to the second metal layer. The connecting unit comprises a contact pad electrically coupled to the first metal layer and the second metal layer.

One aspect of the present disclosure provides another semiconductor structure. The semiconductor structure includes a substrate and N stacking pairs stacked to each other on the substrate. Each of the N stacking pairs comprises a first repeating unit and a second repeating unit. In each of the N stacking pairs, the first repeating unit comprises a first capacitor structure including a first node, a second node and a first metal layer formed in a first interconnect structure, and the second repeating unit comprises a second capacitor structure including a first node, a second node and a second metal layer formed in a second interconnect structure. The first nodes of the first capacitor structure and the second capacitor structure are electrically connected through bonding between the first metal layer and the second metal layer, and the second nodes of the first capacitor structure and the second capacitor structure are electrically connected through bonding between the first metal layer and the second metal layer, and the N is an integer and ≥1.

Another aspect of the present disclosure provides a method for manufacturing a semiconductor structure. The method includes: providing a first wafer including a first substrate, a first dielectric layer on the first substrate, a first device within the first dielectric layer, and a first metal layer over the first device and partially exposed through the first dielectric layer; providing a second wafer including a second substrate, a second dielectric layer on the second substrate, a second device within the second dielectric layer, and a second metal layer over the second device and partially exposed through the second dielectric layer; and bonding the second wafer to the first wafer, wherein the second wafer is disposed over the first wafer, the second metal layer is bonded to the first metal layer, and the second dielectric layer is bonded to the first dielectric layer.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1A shows a semiconductor structure, in accordance with some embodiments of the present disclosure.

FIG. 1B shows a device of the semiconductor structure in FIG. 1A having a capacitor structure.

FIG. 1C shows an enlarged view of a portion encircled by a broken line in FIG. 1B.

FIG. 1D shows an enlarged view of devices and metal layers of the semiconductor structure in FIG. 1A.

FIG. 1E shows another semiconductor structure, in accordance with some embodiments of the present disclosure.

FIG. 2 is a flowchart showing a method of manufacturing the semiconductor structure in FIG. 1A, in accordance with some embodiments of the present disclosure.

FIGS. 3A to 3L are schematic cross-sectional views illustrating sequential operations of the method in FIG. 2, in accordance with some embodiments of the present disclosure.

FIG. 4 is a flowchart showing a method of manufacturing the semiconductor structure in FIG. 1E, in accordance with some embodiments of the present disclosure.

FIGS. 5A to 5I are schematic cross-sectional views illustrating sequential operations of the method in FIG. 4, in accordance with some embodiments of the present disclosure.

### DETAILED DESCRIPTION

The following description accompanies drawings, which are incorporated in and constitute a part of this specification, and which illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure are described in detail below. However, in addition to the detailed description, the present disclosure may also be widely implemented in other embodiments. The scope of the present disclosure is not limited to the detailed description, and is defined by the claims.

A hybrid bonding process bonds two or more semiconductor structures by additional hybrid bonding layers respectively on the semiconductor structures. The hybrid bonding layer includes a bonding metal and a bonding dielectric. The bonding metals respectively on the semiconductor structures are bonded with each other, and the bonding dielectrics respectively on the semiconductor structures are bonded with each other. Such bonding process may have some problems. For example, alignment of the bonding metals may be challenging due to their small dimension. A misalignment of the bonded semiconductor structure may cause electrical failure. The present disclosure provides a method for bonding two or more semiconductor structures without additional hybrid bonding layer. The method provided by the present disclosure can reduce a risk of misalignment of the bonding of semiconductor structures.

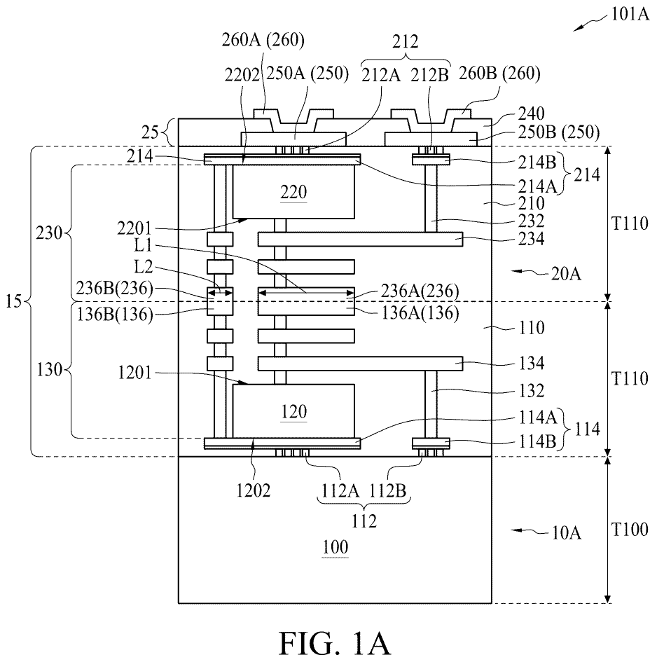

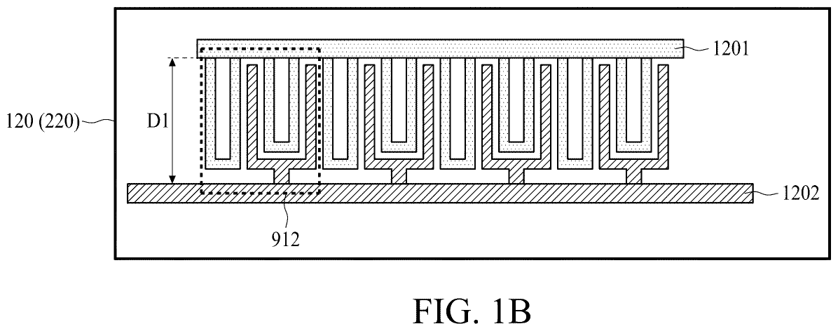

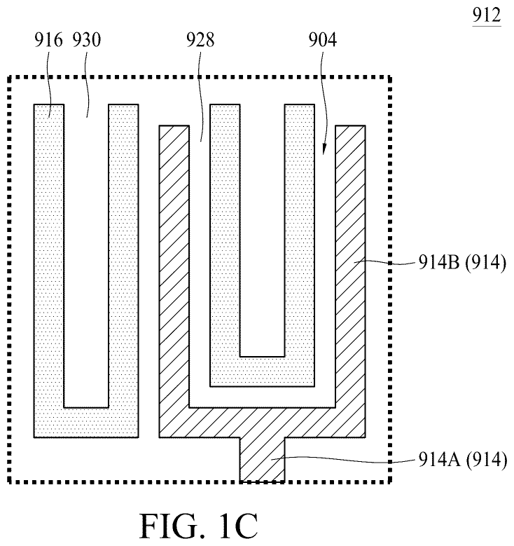

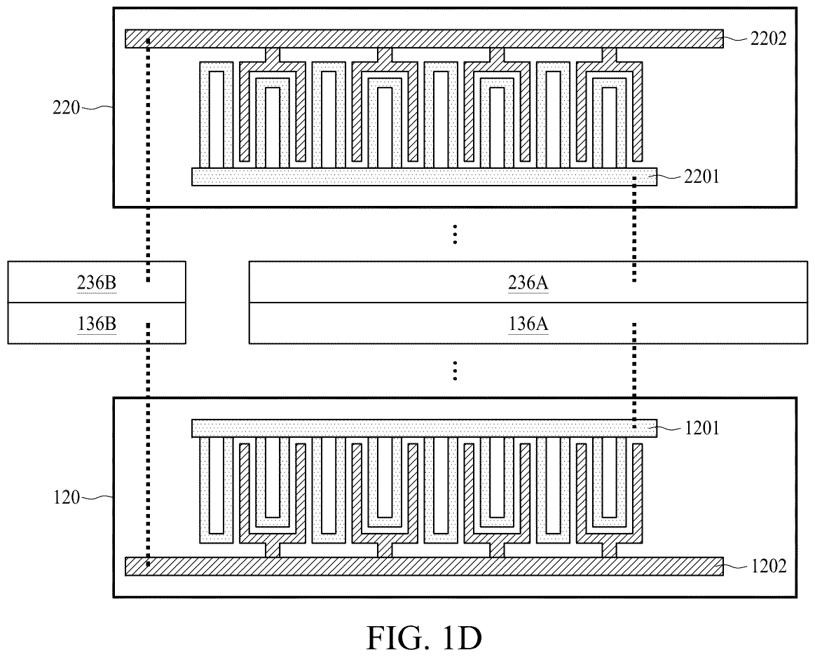

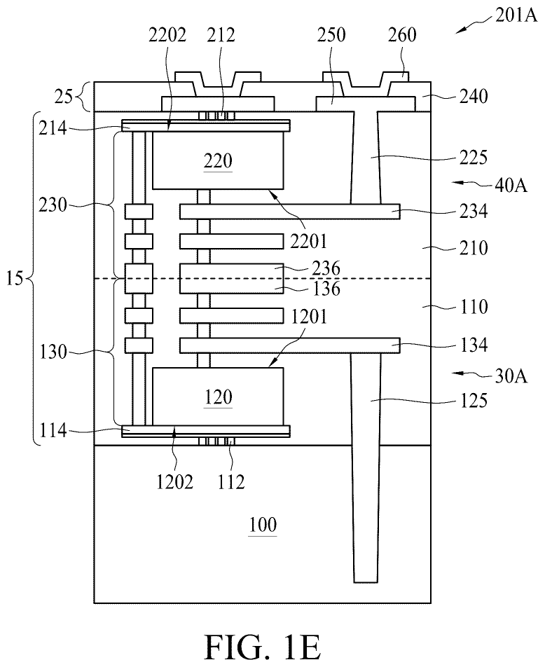

FIG. 1A shows a semiconductor structure 101A, according to some embodiments of the present disclosure. The semiconductor structure 101A includes a first substrate 100, a first stacking pair 15 disposed on the first substrate 100 and a connecting unit 25 disposed on the first stacking pair 15. The first stacking pair 15 includes a first repeating unit 10A bonded to a second repeating unit 20A. The first repeating unit 10A and the second repeating unit 20A are stacked in a front-to-front direction.

The first repeating unit 10A includes a first dielectric layer 110, a first device 120 and a first interconnect structure 130. In some embodiments, the first repeating unit 10A is supported by a first substrate 100. The first dielectric layer 110, the first device 120 and the first interconnect structure 130 are disposed over the first substrate 100. The first device 120 and the first interconnect structure 130 are electrically connected with each other and surrounded by the first dielectric layer 110. In some embodiments, the first substrate 100 is below the first repeating unit 10A and connected to the first dielectric layer 110.

The second repeating unit 20A is disposed over the first repeating unit 10A. The second repeating unit 20A includes a second dielectric layer 210, a second device 220 and a second interconnect structure 230. The second device 220 and the second interconnect structure 230 are electrically connected with each other and surrounded by the second dielectric layer 210.

The first substrate 100 may be a semiconductor substrate such as a bulk silicon (Si) wafer. In some embodiments, the first substrate 100 is a silicon substrate in a die level. In some embodiments, the first substrate 100 is a semiconductor-on-insulator (SOI) substrate, a multi-layered or a gradient substrate, or the like. In some embodiments, the first substrate 100 includes at least one of germanium (Ge), gallium (Ga), arsenic (As), phosphorus (P), indium (In), antimonide, SiGe, SiC, GaAs, GaN, GaP, InGaP, InP, InAs, InSb, GaAsP, AlInAs, AlGaAs, GaInAs, GaInP, GaInAsP, or and other suitable materials. The first substrate 100 includes any type of semiconductor body such as a silicon-on-insulator (SOI) substrate. In some embodiments, the first substrate 100 has a thickness T100 between about 700 micrometers (μm) and about 900 μm.

The second dielectric layer 210 is bonded to the first dielectric layer 110. In some embodiments, the first dielectric layer 110 and the second dielectric layer 210 include silicon oxide (SiO₂), silicon nitride (SiN), silicon carbon nitride (SiCN), undoped silicate glass (USG), phospho-silicate glass (PSG), boro-silicate glass (BSG), boron-doped phospho-silicate glass (BPSG), tetraethyl orthosilicate (TEOS), polymer, or the like. In some embodiments, the first dielectric layer 110 and/or the second dielectric layer 210 includes multiple dielectric layers stacked over each other. The dielectric layers may include a same material or different materials. The first dielectric layer 110 and the second dielectric layer 210 may be referred to as an interlayer dielectric (ILD) or an inter-metal dielectric (IMD). In some embodiments, the first dielectric layer 110 and the second dielectric layer 210 respectively have a thickness T110 between about 3 μm and about 10 μm.

In some embodiments, the first repeating unit 10A includes multiple conductive plugs 112 disposed on the first substrate 100 and surrounded by the first dielectric layer 110. A number of the conductive plugs 112 is not limited. In some embodiments, the conductive plugs 112 include a first set of conductive plugs 112A and a second set of conductive plugs 112B separated from each other. A number of the conductive plugs in each set is not limited.

FIG. 1B shows a schematic cross-sectional view of the first device 120 or the second device 220. In some embodiments, the first device 120 and the second device 220 are or include a 3-dimensional (3D) capacitor respectively. In some embodiments, the 3D capacitor can be a cylinder-type capacitor, crown-type capacitor or concave-type capacitor. In some embodiments, the first device 120 and the second device 220 are or include a 3D metal-insulator-metal (MIM) capacitor respectively, while such out-of-plane dimension can be advantageously used to increase effective MIM area and related capacitance density. In some embodiments, the first device 120 and the second device 220 in the present disclosure respectively may have a very high capacitance density, for example, the capacitor density can be higher than about 1 μF/mm². In some embodiments, the first device 120 is embedded in a mid-end-of line (MEOL) structure of the first repeating unit 10A, and the second device 220 is embedded in a MEOL structure of the second repeating unit 20A.

As shown in FIG. 1B, in some embodiments, each of the first device 120 and the second device 220 includes a bottom conductive plate 1202, a top conductive plate 1201 over the bottom conductive plate 1202 and multiple 3D capacitor unit cells 912 between the bottom conductive plate 1202 and the top conductive plate 1201. In some embodiments, a distance D1 between the bottom conductive plate 1202 and the top metal plate 1201 is in a range of from about 1 μm to about 2 μm, that is substantially less than a size of a conventional active or passive device formed within a deep trench of a substrate such as a conventional deep trench capacitor.

FIG. 1C shows an enlarged view of the 3D capacitor unit cell 912. The 3D capacitor unit cell 912 is a cylinder-type capacitor, a crown-type capacitor or a concave-type capacitor. As illustrated in FIG. 1D, in the embodiment that each of the 3D capacitor unit cells 912 is formed in a crown type.

Referring back to FIG. 1C, the 3D capacitor unit cell 912 includes a first conductive film 914 and a second conductive film 916. The first conductive film 914 and the second conductive film 916 are disposed between the bottom conductive plate 1202 and the top conductive plate 1201. In some embodiments, the first conductive film 914 includes a first portion 914A connected to the bottom conductive plate 1202, and a second portion 914B connected to the first portion 914A and extending toward the top conductive plate 1201 from the bottom conductive plate 1202. In some embodiments, the second conductor film 916 is disposed adjacent to the first conductor film 914, connected to the top conductive plate 1201 and extending toward the bottom conductive plate 1202 from the top conductive plate 1201. In some embodiments, the second conductor film 916 is vertically interleaved with the second portion 914B of the first conductor film 914. For instance, as the cross-sectional view shown in FIG. 1C, the second conductor film 916 is located adjacent to the inner and outer sides of an accommodated space 904. In some embodiments, the accommodated space 904 is surrounded by the first conductor film 914. In some embodiments, the second portion 914B can have a cylindrical shape.

Moreover, the 3D capacitor unit cell 912 further includes a first insulating film 928 for isolating the first conductor film 914 and the second conductor film 916. In other words, stacking of the first conductor film 914, the first insulating film 928 and the second conductor film 916 forms MIM structure of the 3D capacitor unit cell 912. As shown in FIG. 1C, in some embodiments, a second insulating film 930 can optionally be utilized to fill the space between the second conductor film 916 and the top conductive plate 1201. In some embodiments, the first insulating film 928 and the second insulating film 930 respectively include high-k dielectric material. For example, the high-k dielectric material may contain at least one of the oxides of lanthanum (La), hafnium (Hf), and zirconium (Zr).

FIG. 1D shows an enlarged view of the first device 120 and the second device 220 of the semiconductor structure 101A. In some embodiments, the first device 120 includes a first capacitor structure, and the second device 220 includes a second capacitor structure. In some embodiments, the first capacitor structure and the second capacitor structure are electrically connected in parallel. In some embodiments, the first device 120 and the second device 220 use same capacitor structure. In some embodiments, the first device 120 and the second device 220 use same capacitor structure with same capacitor density. In some embodiments, the first device 120 and the second device 220 are electrically connected in parallel. In some embodiments, each of the first capacitor structure and the second capacitor structure of the first device 120 and the second device 220 includes a first node configured to receive a first potential and a second node configured to receive a second potential. The first potential is different from the second potential. In some embodiments, the first potential is a ground (GND) potential, and the second potential is a VDD potential or other operating potential of the first device 120 and the second device 220. In some embodiments, the first potential is a VDD potential and the second potential is a GND potential. In some embodiments, the first node of the first capacitor structure is electrically coupled to the first node of the second capacitor structure, and the second node of the first capacitor structure is electrically coupled to the second node of the second capacitor structure.

In some embodiments, the bottom conductive plate 1202 is the first node, and the top conductive plate 1201 is the second node. In other embodiments, the top conductive plate 1201 is the first node, and the bottom conductive plate 1202 is the second node. In some embodiments, the bottom conductive plate 1202 of the first device 120 is electrically coupled to the bottom conductive plate 2202 of the second device 220, and the top conductive plate 1201 of the first device 120 is electrically coupled to the top conductive plate 2201 of the second device 220, as illustrated by broken lines in FIG. 1D. That is, the first node of the first device 120 is electrically coupled to the first node of the second device 220, and the second node of the first device 120 is electrically coupled to the second node of the second device 220.

In embodiments where the first set of conductive plugs 112A and the second set of conductive plugs 112B are disposed on the first substrate 100, a first conductive plate 114A is disposed on the first set of conductive plugs 112A, and a second conductive plate 114B is disposed on the second set of conductive plugs 112B. In such embodiments, the first conductive plate 114A and the second conductive plate 114B are separated from the substrate 100. The first conductive plate 114A and the second conductive plate 114B are collectively referred to as conductive plates 114.

In some embodiments, the first device 120 is disposed on and electrically connected to the first conductive plate 114A. The first conductive plate 114A is in contact with and disposed between the first device 120 and the first set of conductive plugs 112A. The first conductive plate 114A is disposed between the first device 120 and the first substrate 100. The first conductive plate 114A may function as an electrode of the first device 120. In some embodiments, the first conductive plate 114A is the second node of the first device 120.

The first interconnect structure 130 includes multiple conductive vias 132 and multiple conductive lines 134 connected to each other. The conductive lines 134 are disposed over the first device 120 and extend laterally at different levels in the first dielectric layer 110. A number of the levels of the conductive lines 134 is not limited. The conductive vias 132 extend vertically for connecting the conductive lines 134 at different levels.

In some embodiments, one conductive via 132 is disposed on the second conductive plate 114B and extends partially through the first dielectric layer 110. In some embodiments, such conductive via 132 is electrically connected to the first device 120 via one or more of the conductive lines 134. In some embodiments, another conductive via is disposed on the first conductive plate 114A and adjacent to the first device 120. In some embodiments, the conductive line 134 is electrically coupled to the first node of the first device 120. In some embodiments, the conductive line 134, the conductive via 132 and the second conductive plate 114B are electrically coupled in series to the first node of the first device 120.

The first interconnect structure 130 further includes a first metal layer 136 which is a topmost conductive line of the first interconnect structure 130. The first metal layer 136 is partially surrounded by the first dielectric layer 110. The first metal layer 136 is disposed over and electrically coupled to the first device 120.The first metal layer 136 may include multiple horizontally-disposed metal lines with identical or different lengths.

In some embodiments, the first metal layer 136 includes a first portion 136A and a second portion 136B separated from the first portion 136A. The first portion 136A and the second portion 136B may have identical or different lengths. In some embodiments, the first portion 136A is electrically coupled to the first node of the first device 120. The second portion 136B is electrically coupled to the second node of the first device 120. The second portion 136B is electrically coupled to the first conductive plate 114A through conductive lines and conductive vias in the first interconnect structure 130. The first nodes of the first capacitor structure and the second capacitor structure are electrically coupled to the first portions 136A and 236A of the first metal layer 136 and the second metal layer 236 respectively, and the second nodes of the first capacitor structure and the second capacitor structure are electrically coupled to the second portions 136B and 236B of the first metal layer 136 and the second metal layer 236 respectively.

The second interconnect structure 230 includes multiple conductive vias 232 and multiple conductive lines 234 connected to each other. The conductive lines 234 extend laterally at different levels in the second dielectric layer 210. A number of the levels of the conductive lines 234 is not limited. The conductive vias 232 extend vertically for connecting the conductive lines 234 at different levels.

In some embodiments, the second device 220 is disposed over a topmost conductive line 234 of the second interconnect structure 230. A topmost one of the conductive vias 232 is disposed on such conductive line 234 and extends partially through the second dielectric layer 210. In some embodiments, such conductive via 232 is electrically connected to the second device 220 via one or more of the conductive lines 234. In some embodiments, the second device 220 may include the similar structure with the first device 120. In some embodiments, the second device 220 is stacked over the first device 120 along a stacking direction. The first node of the second device 220 is proximal to the first device 120 along the stacking direction. A second node of the second device 220 is distal to the first device along the stacking direction.

The second interconnect structure 230 further includes a second metal layer 236 which is a bottommost conductive layer of the second interconnect structure 230. The second metal layer 236 is partially surrounded by the second dielectric layer 210. The second metal layer 236 may include multiple horizontally-disposed metal lines with identical or different lengths.

In some embodiments, the second metal layer 236 includes a first portion 236A and a second portion 236B separated from the first portion 236A. The first portion 236A and the second portion 236B may have identical or different lengths. The first portion 236A is electrically coupled to the first node of the second device 220. The second portion 236B is electrically coupled to the second node of the second device 220. The second portion 236B is electrically coupled to the first conductive plate 214A through conductive lines and conductive vias in the second interconnect structure 230.

In some embodiments, the second metal layer 236 of the second interconnect structure 230 is aligned with and bonded to the first metal layer 136 of the first interconnect structure 130. The first metal layer 136 is in direct contact with the second metal layer 236. Each of the horizontally-disposed metal lines of the first metal layer 136 is vertically aligned with each of the horizontally-disposed metal lines of the second metal layer 236, respectively. In some embodiments, the first portion 136A of the first metal layer 136 is aligned with and electrically coupled the first portion 236A of the second metal layer 236. The second portion 136B of the first metal layer 136 is aligned with and electrically coupled to the second portion 236B of the second metal layer 236. In some embodiments, a pattern of the second metal layer 236 substantially corresponds to a pattern of the first metal layer 136. In some embodiments, the pattern layout of the second metal layer 236 is a mirror image of the pattern layout of the first metal layer 136 so that the two pattern layouts matches each other (e.g., metal-to-metal, dielectric-to-dielectric) when the second metal layer 236 bonds face to face to the first metal layer 136. In some embodiments, the second dielectric layer 210 is bonded to the first dielectric layer 110. In some embodiments, a line width of the first metal layer 136 or the second metal layer 236 is in a range from about 1 μm to about 15 μm.

Referring to FIGS. 1A to 1D, in some embodiments, the top conductive plate 1201 of the first device 120 is electrically coupled to the first portion 136A of the first metal layer 136, and the top conductive plate 2201 of the second device 220 is electrically coupled to the first portion 236A of the second metal layer 236. In some embodiments, the bottom conductive plate 1202 of the first device 120 is electrically coupled to the second portion 136B of the first metal layer 136, and the bottom conductive plate 2202 of the second device 220 is electrically coupled to the second portion 236B of the second metal layer 236.

In some embodiments, a length L1 of the bonding face between the first portion 136A and the first portion 236A is different from another length L2 of the bonding face between the second portion 136B and the second portion 236B. In some embodiments, the length L1 is in a range from about 5 μm to about 15 μm. In some embodiments, the first portion 136A and the first portion 236A is electrically coupled to the first nodes of the first device 120 and the second device 220 respectively, and the first nodes of the first device 120 and the second device 220 are respectively configured to receive the first potential which is higher than the second potential configured to supply to the second nodes of the first device 120 and the second device 220. The length L1 is larger than the length L2. In some embodiments, the bonding interface with the longer length (e.g., the length L1) may have lower contact resistance and is selected for the power transmission of high potential to reduce the RC delay. In some embodiments, the length of the first metal layer 136 may be different from the length of the second metal layer 236. By way of example but not limitation, a length of the first portion 136A of the first metal layer 136 is different from a length of the first portion 236A of the second metal layer 236.

In some embodiments, a third conductive plate 214A is disposed on and electrically connected to the second device 220. The third conductive plate 214A may function as an electrode of the second device 220. In some embodiments, a fourth conductive plate 214B is disposed on and electrically connected to the topmost conductive via 232. The third conductive plate 214A and the fourth conductive plate 214B are collectively referred to as conductive plates 214.

In some embodiments, a third set of conductive plugs 212A are disposed on the third conductive plate 214A, and a fourth set of conductive plugs 212B are disposed on the fourth conductive plate 214B. A number of the conductive plugs in each set is not limited. The third set of conductive plugs 212A and the fourth set of conductive plugs 212B are collectively referred to as conductive plugs 212. The third conductive plate 214A is in contact with and disposed between the second device 220 and the third set of conductive plugs 212A. The conductive plugs 212 and the conductive plates 214 are surrounded by the second dielectric layer 210.

In some embodiments, the conductive plugs 112 and 212, the conductive plates 114 and 214, the conductive vias 132 and 232, the conductive lines 134 and 234, the first metal layer 136 and the second metal layer 236 are made of tungsten (W), copper (Cu), cobalt (Co), aluminum (Al), nickel (Ni), tantalum (Ta), titanium (Ti), molybdenum (Mo), palladium (Pd), platinum (Pt), ruthenium (Ru), iridium (Ir), silver (Ag), gold (Au), the like, or a combination thereof. In some embodiments, some of the conductive plugs 112 and 212, the conductive plates 114 and 214, the conductive vias 132 and 232, the conductive lines 134 and 234, the first metal layer 136 and the second metal layer 236 are made by different conductive materials.

In some embodiments, the connecting unit 25 includes a passivation layer 240 and multiple contact pads 250 disposed in the passivation layer 240. In some embodiments, the contact pads 250 are electrically coupled to the first metal layer 136 and the second metal layer 236. In some embodiments, the passivation layer 240 is disposed on the second dielectric layer 210 of the second repeating unit 20A. In some embodiments, the passivation layer 240 is formed of a dielectric material such as undoped silicate glass, silicon nitride, silicon oxide, silicon oxynitride, or the like. In other embodiments, the passivation layer 240 is formed of a polymer material such as epoxy, polyimide, benzocyclobutene (BCB), polybenzoxazole (PBO), or the like. In some embodiments, the passivation layer 240 contacts portions of the second dielectric layer 210.

The third conductive plate 214A is disposed between the second device 220 and the passivation layer 240. The third set of conductive plugs 212A extend between the third conductive plate 214A and the passivation layer 240. The fourth conductive plate 214B is disposed between one of the topmost conductive vias 232 and the passivation layer 240. The fourth set of conductive plugs 212B extend between the fourth conductive plate 214B and the passivation layer 240.

The contact pads 250 are respectively disposed on the underlying conductive plugs 212. The contact pads 250 may be embedded in or at least partially exposed through the passivation layer 240. The contact pads 250 are respectively connected to the third set of conductive plugs 212A and the fourth set of conductive plugs 212B. The contact pads 250 are electrically connected to the second device 220 and the second interconnect structure 230 via the conductive plugs 212 and the conductive plates 214.

In some embodiments, multiple connection pads 260 are respectively disposed on the underlying contact pads 250. Portions of the connection pads 260 are surrounded by the passivation layer 240. In some embodiments, the contact pads 250 include a first contact pad 250A and a second contact pad 250B. The first contact pad 250A is configured to receive a first potential from an external power source, and the first contact pad 250A is electrically coupled to the first nodes of the first device 120 and the second device 220. The second contact pad 250B is configured to receive a second potential from the external power source, and the second contact pad 250B is electrically coupled to the second nodes of the first device 120 and the second device 220. In some embodiments, the first potential is an operating potential, such as VDD potential. The second potential is lower than the first potential (e.g. the operating potential), such as GND potential. In some embodiments, the first device 120 and the second device 220 are electrically connected in parallel.

In some embodiments, the contact plugs 112 may not be required in the first repeating unit 10A. In some embodiments, the conductive via 132, the second conductive plate 114B and the contact plugs 112 may not be required in the first repeating unit 10A. In some embodiments, the contact pads 250 are electrically connected to the second device 220 and the second interconnect structure 230 via the conductive plates 214. The contact plugs 212 are not required in the second repeating unit 20A. In some embodiments, the conductive via 132, the second conductive plate 114B, and the contact plugs 112 and 212 are remain in the first repeating unit 10A and the second repeating unit 20A. In this embodiment, the first repeating unit 10A and the second repeating unit 20A are similar with each other and can be manufactured under similar process conditions to reduce the entire process complexity and cost.

FIG. 1E shows a semiconductor structure 201A, according to some embodiments of the present disclosure. The semiconductor structure 201A in FIG. 1E is similar to the semiconductor structure 101A in FIG. 1A, and identical elements between the semiconductor structure 101A and the semiconductor structure 201A are not repeated for brevity.

The semiconductor structure 201A includes a third repeating unit 30A bonded to a fourth repeating unit 40A. The third repeating unit 30A and the fourth repeating unit 40A are similar to the first repeating unit 10A and the second repeating unit 20A in FIG. 1A, respectively. In some embodiments, one of the conductive vias 132 of the first repeating unit 10A is replaced by a first through via 125, and one of the conductive vias 232 of the second repeating unit 20A is replaced by a second through via 225. The first through via 125 may be a part of the first interconnect structure 130, and the second through via 225 may be a part of the second interconnect structure 230. In some embodiment, the first through via 125 is electrically coupled to the first device 120, and the second through via 225 is electrically coupled to the second device 220. In some embodiments, the first through via 125 extends vertically from the first dielectric layer 110 into the first substrate 100. The first through via 125 is electrically connected to the first interconnect structure 130. In some embodiments, the first through via 125 extends toward and into the first substrate 100. In some embodiments, the second through via 225 is vertically disposed in the second dielectric layer 210. In some embodiments, the second through via 225 extends toward and contacts one of the contact pads 250. The second through via 225 is electrically connected to the contact pad 250. The second through via 225 is electrically connected to the second interconnect structure 230.

In some embodiments, the contact plugs 112 and the first through via 125 may not be required in the third repeating unit 30A. In some embodiments, the contact plugs 112 and the first through via 125 are remain in the third repeating unit 30A. In this embodiment, the third repeating unit 30A and the fourth repeating unit 40A are similar with each other and can be manufactured under similar process conditions to reduce the entire process complexity and cost.

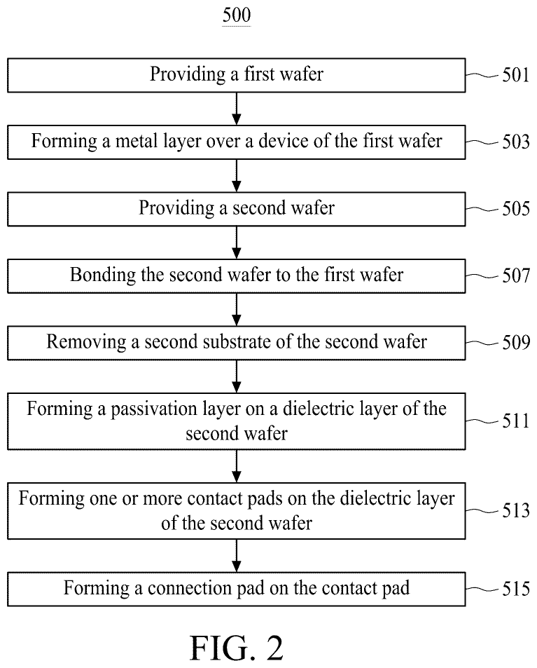

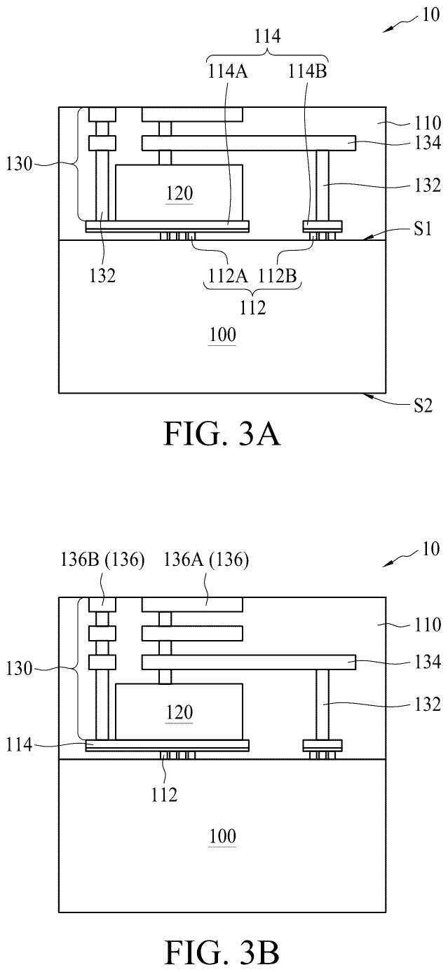

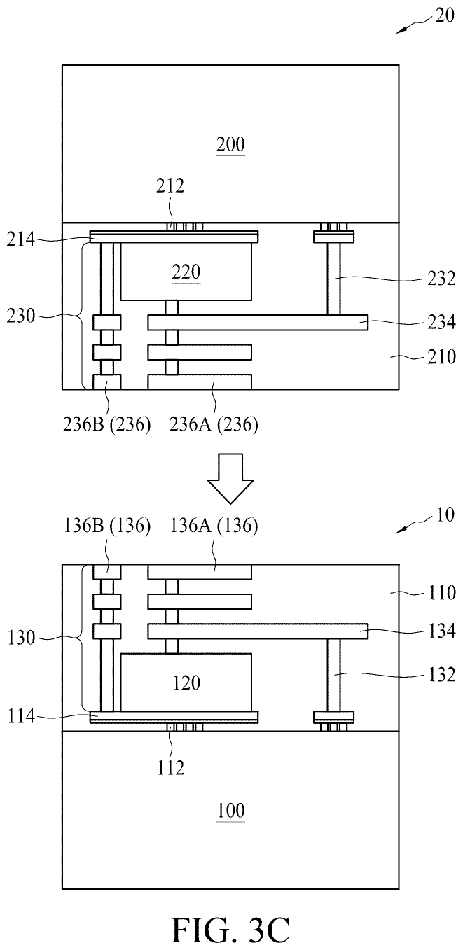

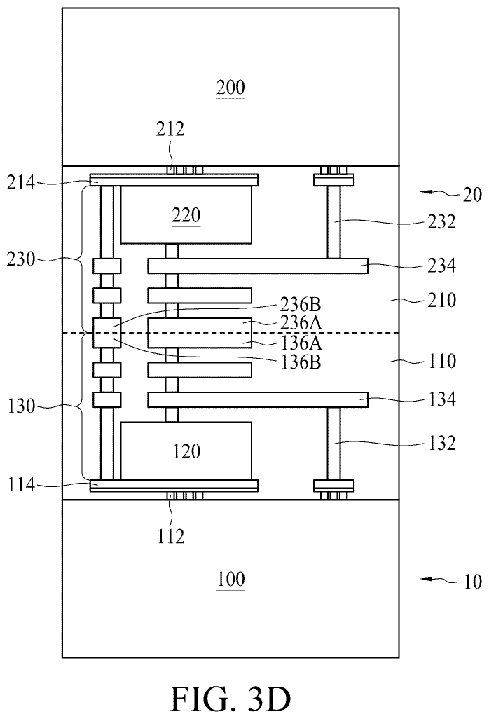

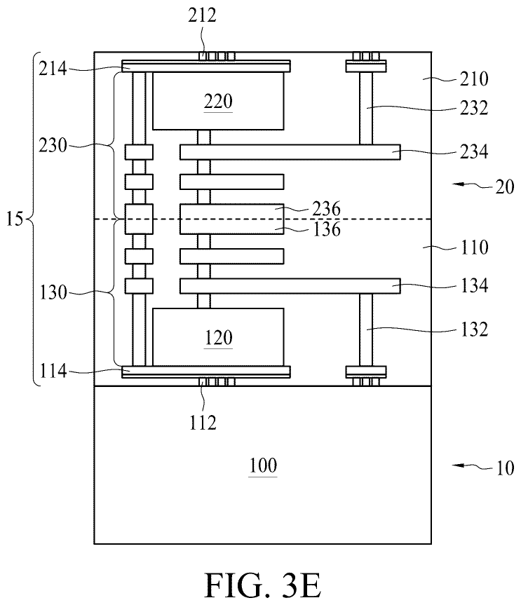

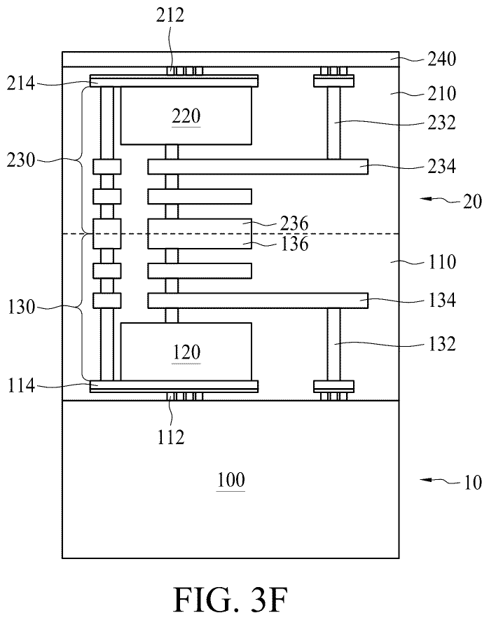

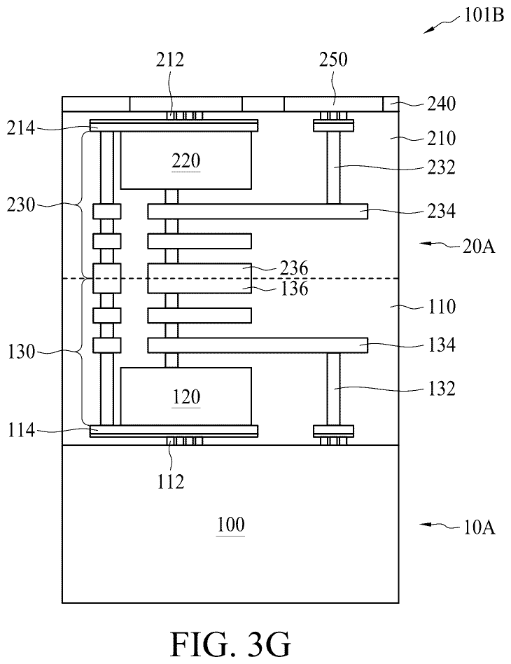

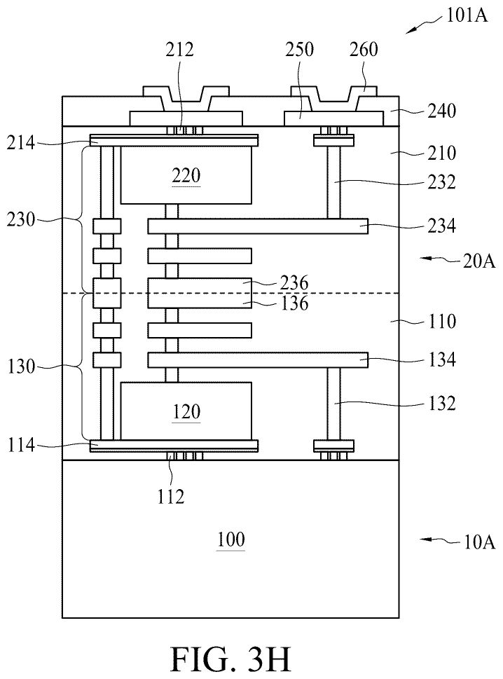

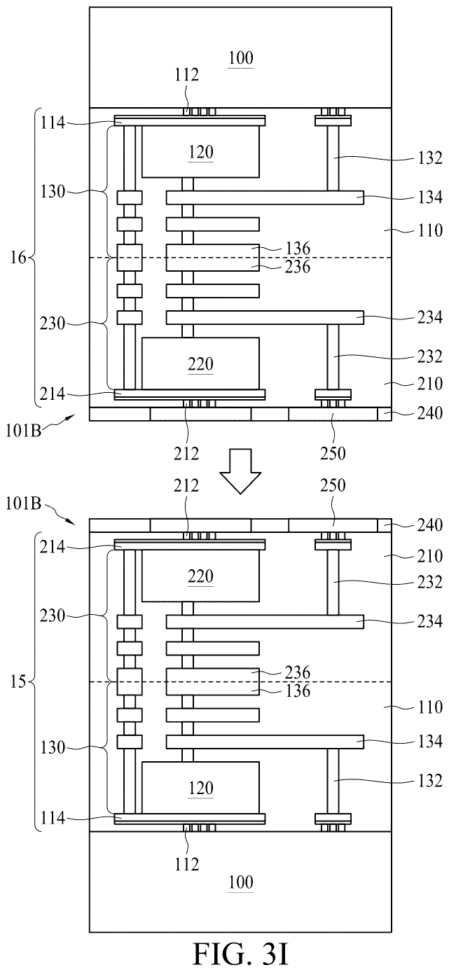

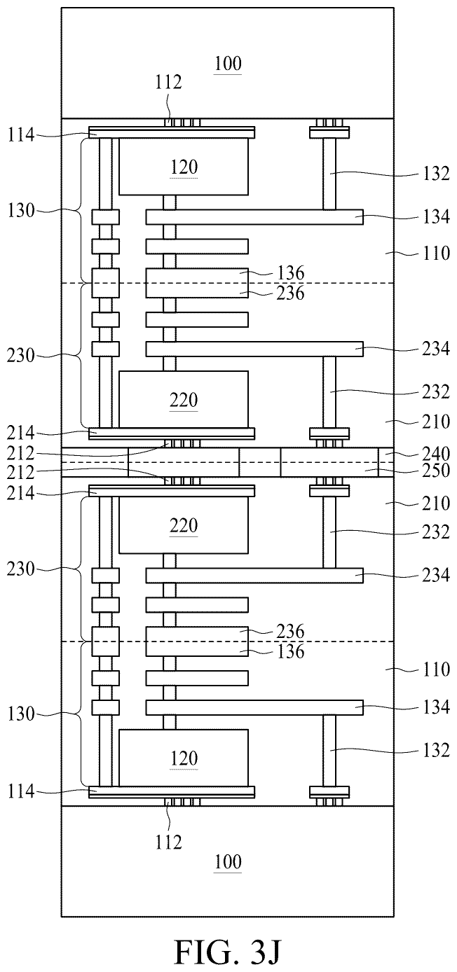

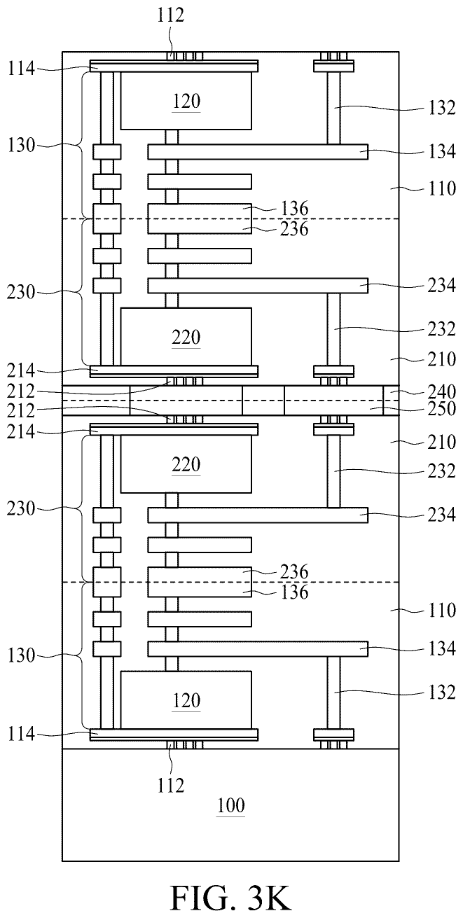

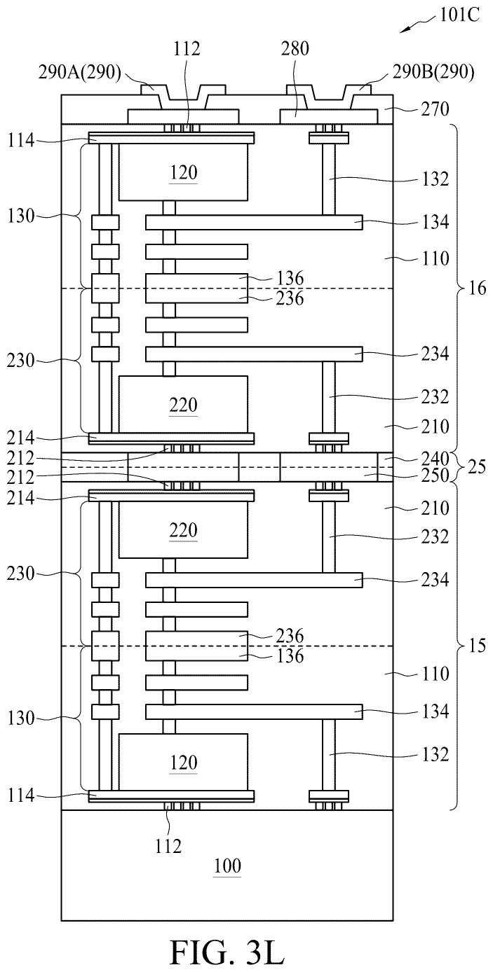

FIG. 2 is a flowchart showing a method 500 for manufacturing the semiconductor structure 101A in FIG. 1A, according to some embodiments of the present disclosure. The method 500 includes a number of operations and the description and illustrations are not deemed as a limitation to the sequence of the operations. FIGS. 3A to 3L are schematic cross-sectional views illustrating sequential operations of the method 500 in FIG. 2.

In operation 501 of FIG. 2, a first wafer 10 is provided, as shown in FIG. 3A. The first wafer 10 includes a first substrate 100, a first dielectric layer 110 formed on the first substrate 100, and a first device 120 and a first interconnect structure 130 formed within the first dielectric layer 110. The first substrate 100 has a first surface S1 and a second surface S2 opposite to the first surface S1. Structures formed over the first surface S1 may be referred to as back-end-of-line (BEOL) structures.

In some embodiments, a first conductive plate 114A is formed on the first set of conductive plugs 112A, and a second conductive plate 114B is formed on the second set of conductive plugs 112B. In such embodiments, the first conductive plate 114A and the second conductive plate 114B are separated from the first surface S1 of the first substrate 100. The first conductive plate 114A and the second conductive plate 114B may be collectively referred to as conductive plates 114. The conductive plates 114 may be made of a material same as or similar to that of the conductive plugs 112. In some embodiments, the first device 120 is formed on and electrically connected to the first conductive plate 114A. The first conductive plate 114A may function as an electrode of the first device 120. The first conductive plate 114A is disposed between the first device 120 and the first substrate 100.

In some embodiments, the first interconnect structure 130 includes multiple conductive vias 132 and multiple conductive lines 134 connected to each other. The conductive lines 134 extend laterally at different levels in the first dielectric layer 110, and the conductive vias 132 extend vertically for connecting the conductive lines 134 at different levels. A number of the levels of the conductive lines 134 is not limited. The first interconnect structure 130 may be made of a material same as or similar to that of the conductive plugs 112. In some embodiments, one conductive via 132 is formed on the first conductive plate 114A and adjacent to the first device 120, and another conductive via 132 is formed on the second conductive plate 114B. In some embodiments, the conductive lines 134 are formed over the first device 120. In some embodiments, the first interconnect structure 130 is configured to facilitate electrical routing between devices, such as capacitors, formed above the first surface S1 of the first substrate 100, thereby enabling formation of a desired circuit.

In operation 503 of FIG. 2, a first metal layer 136 is formed over the first device 120 of the first wafer 10, as shown in FIG. 3B. Although not specifically illustrated in FIG. 3B, the first metal layer 136 may be formed using a series of processes such as deposition, photolithography, etching, planarization, or the like. The first metal layer 136 includes a first portion 136A and a second portion 136B separated from the first portion 136A. The first portion 136A is electrically coupled to the first node 1201 of the first device 120. The second portion 136B is electrically coupled to the second node 1202 of the first device 120. The first portion 136A and the second portion 136B of the first metal layer 136 may have the different size. In some embodiments, the sizes of the first portion 136A and the second portion 136B may be designed according to the potential requirements of the first node and the second node of the first device 120. For example but not limitation, the first node of the first device 120 may be designed to receive the operation potential which requires the lower resistance during power transmission, the first portion 136A of the first metal layer 136 may be designed to have a larger size or wider length to reduce the contact resistance in the following bonding process. For example but not limitation, the second portion 136B of the second metal layer 136 may be designed to receive a low potential, such as GND potential or other potential lower than the operation potential, the second portion 136B may be designed to have a smaller size or shorter length comparing with the first portion 136A. In some embodiments, the first metal layer 136 is made of aluminum or copper, but the present disclosure is not limited thereto. The first metal layer 136 may be considered part of the first interconnect structure 130. A top surface of the first metal layer 136 is exposed through the first dielectric layer 110 for subsequent operations. In some embodiments, the first metal layer 136 is one topmost layer of the first interconnect structure 130, and the first interconnect structure 130 is formed in the BEOL structure.

In operation 505 of FIG. 2, a second wafer 20 is provided, as shown in FIG. 3C. The second wafer 20 may be another first wafer 10 or a wafer similar to the first wafer 10. For convenience of discussion, elements in the second wafer 20 that are identical to elements in the first wafer 10 are represented by reference numerals of the elements in the first wafer 10 plus 100. In some embodiments, the second wafer 20 includes a second substrate 200, a second dielectric layer 210, conductive plugs 212, conductive plates 214, a second device 220 and a second interconnect structure 230. The second dielectric layer 210 is formed on the second substrate 200. The conductive plugs 212, the conductive plates 214, the second device 220 and the second interconnect structure 230 are formed within the second dielectric layer 210.

The second interconnect structure 230 includes multiple conductive vias 232 and multiple conductive lines 234. The second interconnect structure 230 includes a second metal layer 236 which is a bottommost conductive line of the second interconnect structure 230 after the flip of the second wafer 20. In some embodiments, the second metal layer 236 is made of aluminum or copper, but the present disclosure is not limited thereto. The second metal layer 236 includes a first portion 236A and a second portion 236B. Similar with the first metal layer 136. The first portion 236A and the second portion 236B of the second metal layer 236 are coupled to the first node 2201 and the second node 2202 of the second device 220 respectively. The first portion 236A and the second portion 236B of the second metal layer 236 may have different size or different length. In some embodiments, the first portion 136A of the first metal layer 136 is electrically and directly connected to the first portion 236A of the second metal layer 236, and the second portion 136B of the first metal layer 136 is electrically and directly connected to the second portion 236B of the second metal layer 236.

The second wafer 20 is flipped upside down and disposed over the first wafer 10. The second metal layer 236 of the second wafer 20 is aligned with the first metal layer 136 of the first wafer 10. In more detail, the first portion 236A of the second metal layer 236 is aligned with the first portion 136A of the first metal layer 136. The second portion 236B of the second metal layer 236 is aligned with the second portion 136B of the first metal layer 136.

In operation 507 of FIG. 2, the second wafer 20 is bonded to the first wafer 10, as shown in FIG. 3D. In some embodiments, the second metal layer 236 is attached to the first metal layer 136, and the second dielectric layer 210 is attached to the first dielectric layer 110. For example, a front surface of the first wafer 10 is a surface proximal to the first metal layer 136 and distal to the substrate 100. A backside surface of the first wafer 10 is opposite to the front surface. In a similar way, a front surface of the second wafer 20 is a surface proximal to the second metal layer 236 and distal to the substrate 200. A backside surface of the second wafer 20 is opposite to the front surface. The bonding of the first wafer 10 to the second wafer 20 may be referred to as a front-to-front or face-to-face (F2F) wafer bonding. In some embodiments, a heating process such as annealing is used to expedite the bonding between the first wafer 10 and the second wafer 20. However, the present disclosure is not limited thereto.

In operation 509 of FIG. 2, the second substrate 200 of the second wafer 20 is removed, as shown in FIG. 3E. In some embodiments, the second substrate 200 is removed using a grinding, planarizing or etching process. In some embodiments, the second substrate 200 is removed by dry etching. The conductive plugs 212 can be used as an indicator to show a stop signal of the dry etching. For example, when a material of the conductive plugs 212 is detected during the dry etching, the dry etching is stopped. That is, the conductive plugs 212 function as a grinding stopper or an etch stopper which can increase a process reliability. In such embodiments, the grinding, planarizing or etching process stops once top surfaces of the conductive plugs 212 are exposed. In some embodiments, the second substrate 200 is removed by wet etching with highly selective etching solution for silicon substrate. The second dielectric layer 210 and the conductive plugs 212 of the second wafer 20 are exposed after an entirety of the second substrate 200 is removed. The conductive plugs 212 may be partially consumed but still remain on the conductive plate 214. After the second substrate 200 is removed, the conductive plates 214 are still embedded in the second dielectric layer 210.

In some embodiments, a stress-relief film (not shown) is disposed between the second substrate 200 and the second dielectric layer 210. In some embodiments, the stress-relief film relieves the generated stress between the second substrate 200 and the second dielectric layer 210. The stress-relief film may include silicon nitride or other suitable materials. In some embodiments, before the second dielectric layer 210 is deposited on the second substrate 200, the stress-relief film is formed on the second substrate 200. In other embodiments, in order to minimize generation of stress, the removal of the second substrate 200 employs a soft polishing or wet polishing process. In other embodiments, before the second substrate 200 is ground, the second wafer 20 is annealed to a predetermined temperature to soften the second substrate 200, without adversely affecting the second device 220.

In operation 511 of FIG. 2, a passivation layer 240 is formed on the second dielectric layer 210 of the second wafer 20, as shown in FIG. 3F. The passivation layer 240 may be formed using chemical vapor deposition (CVD), physical vapor deposition (PVD), or other suitable methods.

In operation 513 of FIG. 2, one or more contact pads 250 are formed on the second dielectric layer 210 of the second wafer 20, as shown in FIG. 3G. Multiple openings exposing the top surfaces of the conductive plugs 212 may be formed in the passivation layer 240 using photolithographic and etching processes. A conductive material such as copper is deposited into such openings using sputtering, electroplating, PVD, or other suitable methods. A planarizing process, such as chemical mechanical polishing (CMP), is used to remove excess conductive material over a top surface of the passivation layer 240, thus forming the contact pads 250. In some embodiments, the contact pads 250 are electrically connected to the second device 220 and the second interconnect structure 230 via the conductive plugs 212 and the conductive plates 214. At this stage, a semiconductor structure 101B is formed.

In operation 515 of FIG. 2, a connection pad 260 is formed on the contact pad 250, as shown in FIG. 3H. In some embodiments, an additional dielectric material or polymer material is deposited to cover the contact pads 250 to thicken the passivation layer 240. Multiple openings exposing top surfaces of the contact pads 250 may be formed in the thickened passivation layer 240 using photolithographic and etching processes. A conductive material such as aluminum is deposited into such openings using sputtering, electroplating, PVD or other suitable methods. An etching process is used to remove portions of the conductive material, thus forming the connection pads 260. The connection pad 260 is electrically connected to the contact pad 250 for providing an external electrical connection. At this stage, the semiconductor structure 101A is formed. The semiconductor structure 101B can be further processed to form a semiconductor structure 101C, as shown in FIGS. 3I to 3L.

Referring to FIG. 3I, two semiconductor structures 101B are provided. One of the semiconductor structures 101B is flipped upside down and disposed over the other semiconductor structure 101B. The flipped semiconductor structure 101B includes a second stacking pair 16, which is substantially identical to the first stacking pair 15. The contact pad 250 is partially surrounded by the passivation layers 240, and a top surface of the contact pad 250 is exposed. Respective contact pads 250 of the two semiconductor structures 101B are aligned with each other.

Referring to FIG. 3J, the upper semiconductor structure 101B is attached to the lower semiconductor structure 101B. In some embodiments, respective contact pads 250 of the two semiconductor structures 101B are bonded to each other. That is, the upper contact pads 250 are in contact with the lower contact pads 250, respectively. In some embodiments, respective passivation layers 240 are bonded to each other. The bonding of the two semiconductor structures 101B may be referred to as a back-to-back (B2B) wafer bonding. In some embodiments, a heating process such as annealing is used to expedite the bonding between the upper and lower contact pads 250. However, the present disclosure is not limited thereto.

Referring to FIG. 3K, the first substrate 100 of the upper semiconductor structure 101B (i.e., the upper first substrate 100) is removed. In some embodiments, the upper first substrate 100 is removed using a grinding, planarizing or etching process. In some embodiments, the grinding, planarizing or etching process stops once top surfaces of the upper conductive plugs 112 are exposed. The first dielectric layer 110 and the conductive plugs 112 of the upper semiconductor structure 101B are exposed after the upper first substrate 100 is removed. The exposed conductive plugs 112 may be partially consumed but still remain on the upper conductive plate 114.

Referring to FIG. 3L, a passivation layer 270 is formed on the exposed upper first dielectric layer 110 and the conductive plugs 112. The passivation layer 270 may be formed of a material similar or identical to that of the passivation layer 240. One or more contact pads 280 are formed in the passivation layer 270. A connection pad 290 is formed on each contact pad 280. The connection pad 290 is electrically connected to the contact pad 280 for providing an external electrical connection. The passivation layer 270, the contact pad 280 and the connection pad 290 may be formed using methods similar to those of operations 511, 513 and 515. At this stage, the semiconductor structure 101C is formed. In some embodiments, the connection pads 290 include a first connection pad 290A and a second connection pad 290B. Similar with the semiconductor device 101A, the first connection pad 290A is electrically coupled to the first nodes of the two first devices 120 and the two second devices 220. The second connection pad 290B is electrically coupled to the second nodes of the two first devices 120 and the two second devices 220. The four devices, such as the two first devices 120 and the two second devices 220 are electrically connected in parallel connection.

Still referring to FIG. 3L, the semiconductor structure 101C includes the first stacking pair 15 and the second stacking pair 16 stacked over the first stacking pair 15. In some embodiments, the first stacking pair 15 and the second stacking pair 16 are stacked in a back-to-back (B2B) direction. In some embodiments, the first repeating unit 10A and the second repeating unit 20A of the second stacking pair 16 are stacked in a front-to-front direction. In some embodiments, the first and second metal layers 130 and 230 in the first stacking pair 15 and the first and second metal layers 130 and 230 in the second stacking pair 16 are electrically coupled to the contact pad 250. The connecting unit 25 is interposed between the first stacking pair 15 and the second stacking pair 16. The bonded contact pads 250 of the connecting unit 25 be referred to as intermediate connecting pads. The intermediate connecting pads are electrically coupled to the second interconnect structures 230 of the first stacking pair 15 and the second stacking pair 16. In some embodiments, the first nodes of the first device 120 and the second device 220 of the first stacking pair 15 and the first nodes of the first device 120 and the second device 220 of the second stacking pair 16 are electrically coupled together, and the second nodes of the first device 120 and the second device 220 of the first stacking pair 15 and the second nodes of the first device 120 and the second device 220 of the second stacking pair 16 are electrically coupled together.

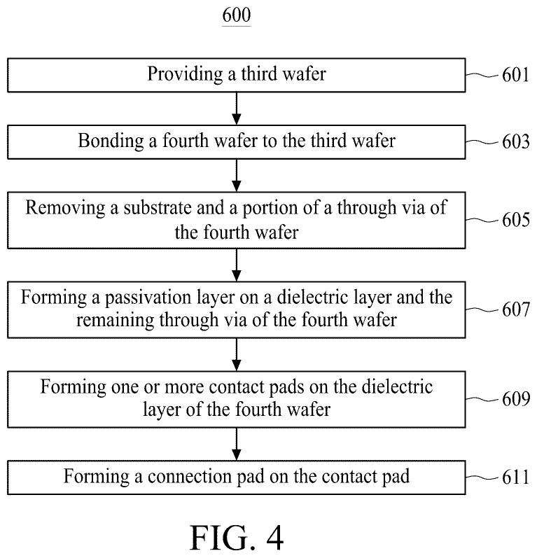

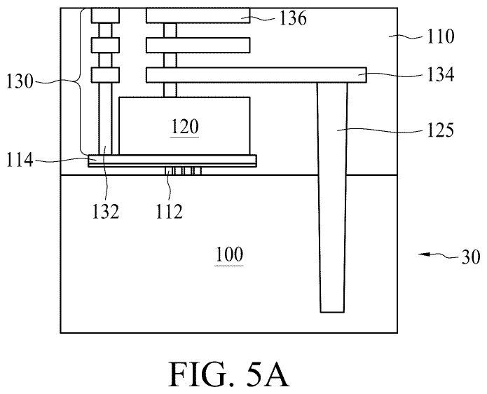

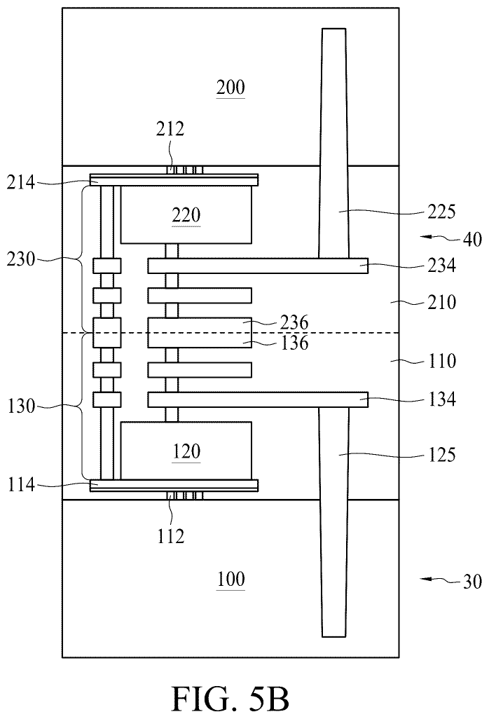

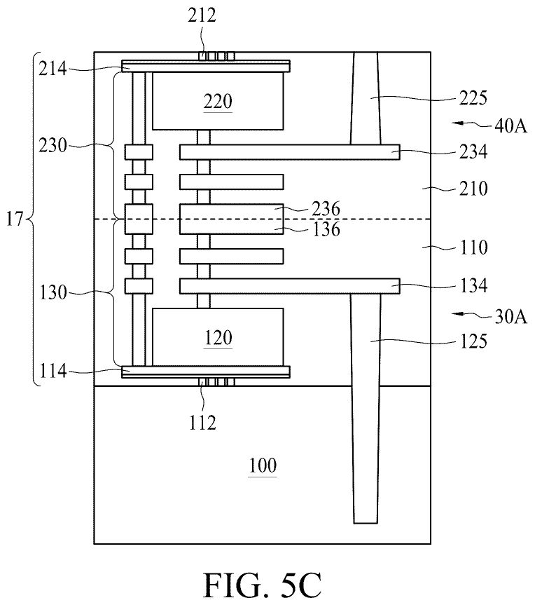

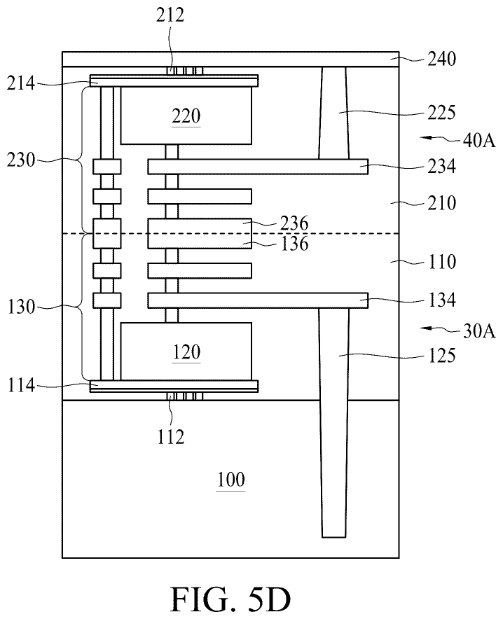

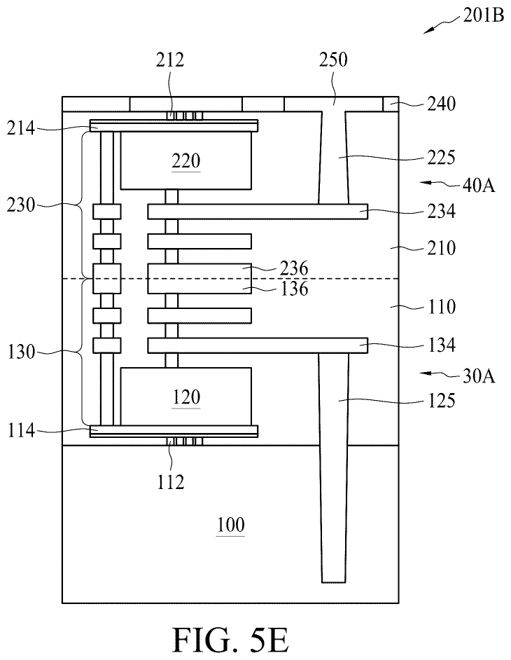

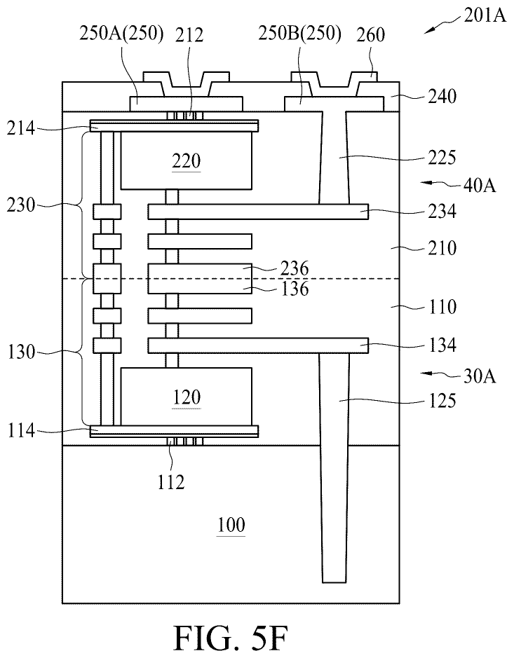

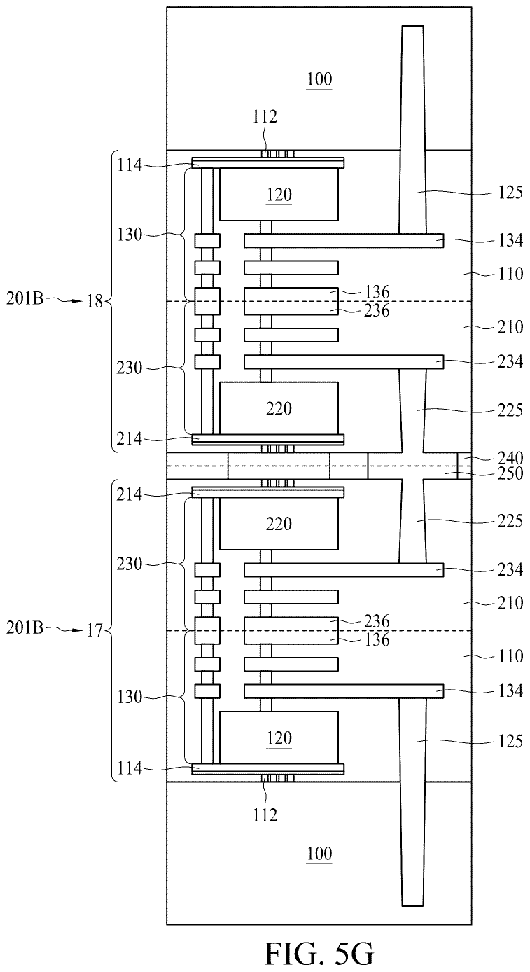

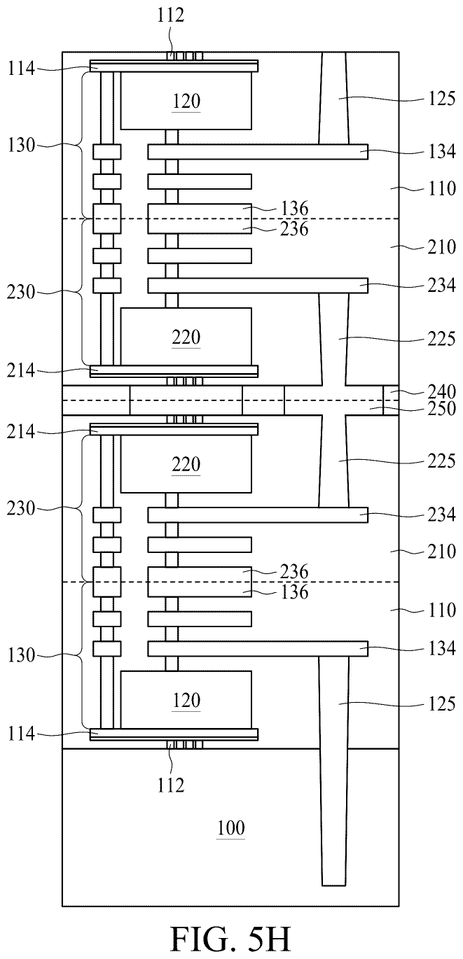

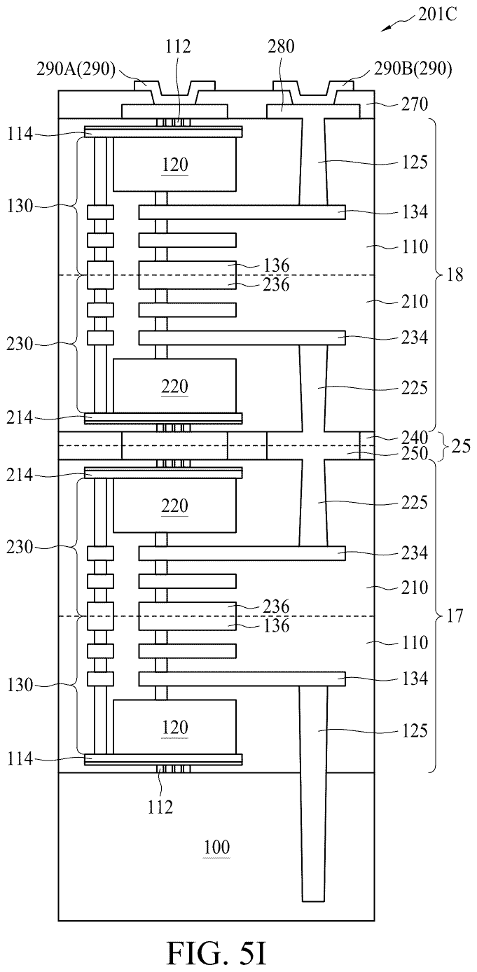

FIG. 4 is a flow chart showing a method 600 for manufacturing the semiconductor structure 201A in FIG. 1B, according to some embodiments of the present disclosure. The method 600 includes a number of operations and the description and illustrations are not deemed as a limitation to the sequence of the operations. FIGS. 5A to 5I are schematic cross-sectional views illustrating sequential operations of the method 600 in FIG. 4. The method 600 in FIG. 4 is similar to the method 500 in FIG. 2 in many aspects. Therefore, repeated or similar descriptions are omitted for brevity.

In operation 601 of FIG. 4, a third wafer 30 is provided, as shown in FIG. 5A. The third wafer 30 is similar to the first wafer 10 in FIG. 2A. The third wafer 30 includes a first substrate 100, a first dielectric layer 110 formed on the first substrate 100, and a first device 120 and a first interconnect structure 130 formed within the first dielectric layer 110.

In some embodiments, the third wafer 30 includes a first through via 125 extending vertically from the first dielectric layer 110 to the first substrate 100. In some embodiments, the first through via 125 is electrically connected to one of the conductive lines 134 of the first interconnect structure 130. In some embodiments, a liner oxide (not shown) is formed between the first through via 125 and the first substrate 100. The first through via 125 is electrically isolated from the first substrate 100.

In some embodiments, the conductive plugs 112, the conductive plates 114, the conductive lines 134 and the first through via 125 are made of tungsten, copper, cobalt, aluminum, nickel, tantalum, titanium, molybdenum, palladium, platinum, ruthenium, iridium, silver, gold, the like, or a combination thereof.

The first interconnect structure 130 includes a first metal layer 136 which is a topmost conductive line of the first interconnect structure 130. In some embodiments, the first metal layer 136 is made of aluminum or copper, but the present disclosure is not limited thereto.

The first metal layer 136 may include multiple horizontally-disposed conductive lines with identical or different lengths. Top surfaces of the conductive lines are exposed through the first dielectric layer 110 for subsequent operations.

In operation 603 of FIG. 4, a fourth wafer 40 is bonded to the third wafer 30, as shown in FIG. 5B. The fourth wafer 40 may be another third wafer 30 or a wafer substantially identical to the third wafer 30. For convenience of mentioning, elements in the fourth wafer 40 that are identical to elements in the third wafer 30 are represented by reference numerals of the elements in the third wafer 30 plus 100. In some embodiments, the fourth wafer 40 includes a second substrate 200, a second dielectric layer 210, conductive plugs 212, a conductive plate 214, a second device 220, a second through via 225 and a second interconnect structure 230. The second dielectric layer 210 is formed on the second substrate 200. The conductive plugs 212, the conductive plate 214, the second device 220, and the second interconnect structure 230 are formed within the second dielectric layer 210.

The second through via 225 extends vertically from the second dielectric layer 210 to the second substrate 200. The second through via 225 is electrically connected to the second interconnect structure 230. In some embodiments, a liner oxide (not shown) is formed between the second through via 225 and the second substrate 200. In some embodiments, similar with the first through via 125, the second through via 225 is electrically isolated from the second substrate 200.

The second interconnect structure 230 includes multiple conductive lines 234. The second interconnect structure 230 includes a second metal layer 236 which is a bottommost conductive line of the second interconnect structure 230 after the fourth wafer 40 is flipped. In some embodiments, the second metal layer 236 is made of aluminum or copper, but the present disclosure is not limited thereto.

The fourth wafer 40 is flipped upside down and disposed over the third wafer 30. Before bonding, the second metal layer 236 of the fourth wafer 40 is aligned with the first metal layer 136 of the third wafer 30. The second metal layer 236 is then attached to the first metal layer 136, and the second dielectric layer 210 is attached to the first dielectric layer 110. The bonding of the third wafer 30 to the fourth wafer 40 may be referred to as an F2F wafer bonding. In some embodiments, a heating process such as annealing is used to expedite the bonding between the third wafer 30 and the fourth wafer 40. However, the present disclosure is not limited thereto.

In operation 605 of FIG. 4, the second substrate 200 and a portion of the second through via 225 of the fourth wafer 40 are removed, as shown in FIG. 5C. In some embodiments, a grinding, planarizing or etching process is performed on the second substrate 200. In some embodiments, the grinding, planarizing or etching process stops once top surfaces of the conductive plugs 212 are exposed. An entirety of the second substrate 200 is removed and a portion of the second through via 225 is consumed. The second dielectric layer 210 and the conductive plugs 212 of the fourth wafer 40 are thus exposed. The conductive plugs 212 may be partially consumed but still remain on the conductive plate 214. After the second substrate 200 is removed, the conductive plate 214 is still embedded in the second dielectric layer 210. As illustrated in FIG. 5C, a structure between the first substrate 100 and a remaining structure of the fourth wafer 40 may be referred to as a third repeating unit 30A, and the remaining structure of the fourth wafer 40 may be referred to as a fourth repeating unit 40A. At this stage, the third repeating unit 30A and the fourth repeating unit 40A together form a first stacking pair 17. In some embodiments, the first stacking pair 17 is similar to the first stacking pair 15 in FIG. 3E, except that the first stacking pair 17 includes through vias such as the first through via 125.

In operation 607 of FIG. 4, a passivation layer 240 is formed on the second dielectric layer 210 and the remaining second through via 225 of the fourth wafer 40, as shown in FIG. 5D.

In operation 609 of FIG. 4, one or more contact pads 250 are formed on the second dielectric layer 210 of the fourth wafer 40, as shown in FIG. 5E. Multiple openings respectively exposing the top surfaces of the conductive plugs 212 and the second through via 225 may be formed in the passivation layer 240 using photolithographic and etching processes. A conductive material such as copper is deposited into such openings using sputtering, electroplating, PVD or other suitable methods. A planarizing process, such as CMP, is used to remove excess conductive material over a top surface of the passivation layer 240, thus forming the contact pads 250.

In embodiments where the fourth wafer 40 does not include any conductive plug 212, the contact pads 250 are respectively disposed on the underlying conductive plate 214 and the second through via 225. In some embodiments, at least one of the contact pads 250 is electrically connected to the second device 220 via the conductive plugs 212 and the conductive plate 214. In some embodiments, at least one of the contact pads 250 is electrically connected to the second interconnect structure 230 via the second through via 225. At this stage, a semiconductor structure 201B is formed.

In operation 611 of FIG. 4, a connection pad 260 is formed on the contact pad 250, as shown in FIG. 5F. In some embodiments, an additional dielectric material or polymer material is deposited to cover the contact pads 250 to thicken the passivation layer 240. One or more openings exposing top surfaces of the contact pads 250 may be formed in the thickened passivation layer 240 using photolithographic and etching processes. A conductive material such as aluminum is deposited into such openings using sputtering, electroplating, PVD or other suitable methods. An etching process is used to remove portions of the conductive material, thus forming the connection pads 260. The connection pad 260 is electrically connected to the contact pad 250 for providing an external electrical connection. At this stage, the semiconductor structure 201A is formed. In some embodiments, the contact pads 250 include a first contact pad 250A and a second contact pad 250B. Similar with the semiconductor device 101A, the first contact pad 250A is electrically coupled to the first nodes of the first device 120 and the second device 220. The second contact pad 250B is electrically coupled to the second nodes of the first device 120 and the second device 220. The first device 120 and the second device 220 are electrically connected in parallel connection.

The semiconductor structure 201B can be further processed to form a semiconductor structure 201C, as shown in FIGS. 5G to 5I.

Referring to FIG. 5G, two semiconductor structures 201B are provided. One of the semiconductor structures 201B is flipped upside down and disposed over the other semiconductor structure 201B. The flipped semiconductor structure 201B includes a second stacking pair 18, which is substantially identical to the first stacking pair 17. The contact pads 250 are partially surrounded by the passivation layers 240, and a top surface of each contact pad 250 is exposed. Respective contact pads 250 of the two semiconductor structures 201B are aligned with each other. The upper semiconductor structure 201B is attached to the lower semiconductor structure 201B. In some embodiments, respective contact pads 250 of the two semiconductor structures 201B are bonded to each other. That is, the upper contact pads 250 are in contact with the lower contact pads 250, respectively. In some embodiments, respective passivation layers 240 are bonded to each other. The bonding of the two semiconductor structures 201B may be referred to as a B2B wafer bonding. In some embodiments, a heating process such as annealing is used to expedite the bonding between the upper and lower contact pads 250. However, the present disclosure is not limited thereto.

Referring to FIG. 5H, the first substrate 100 and a portion of the first through via 125 of the upper semiconductor structure 201B (i.e., the upper first substrate 100 and a portion of the upper first through via 125) are removed. In some embodiments, a grinding, planarizing or etching process is performed on the upper first substrate 100. In some embodiments, the grinding, planarizing or etching process stops once top surfaces of the upper conductive plugs 112 are exposed. An entirety of the upper first substrate 100 is removed and a portion of the upper first through via 125 are consumed. The first dielectric layer 110 and the conductive plugs 112 of the upper semiconductor structure 201B are exposed after the upper first substrate 100 is removed. The exposed conductive plugs 112 may be partially consumed but still remain on the conductive plate 114.

Referring to FIG. 5I, a passivation layer 270 is formed on the exposed first dielectric layer 110, the conductive plugs 112 and the upper first through via 125. The passivation layer 270 may be formed of a material similar or identical to that of the passivation layer 240. One or more contact pads 280 are formed in the passivation layer 270. A connection pad 290 is formed on each contact pad 280. The connection pad 290 is electrically connected to the contact pad 280 for providing an external electrical connection. The passivation layer 270, the contact pads 280 and the connection pad 290 may be formed using methods similar to those of operations 607, 609 and 611. At this stage, the semiconductor structure 201C is formed. In some embodiments, the connection pads 290 include a first connection pad 290A and a second connection pad 290B. Similar with the semiconductor device 101C, the first connection pad 290A is electrically coupled to the first nodes of the two first devices 120 and the two second devices 220. The second connection pad 290B is electrically coupled to the second nodes of the two first devices 120 and the two second devices 220. The four devices, such as the two first devices 120 and the two second devices 220 are electrically connected in parallel connection.

Still referring to FIG. 5I, the semiconductor structure 201C includes the first stacking pair 17 and the second stacking pair 18 stacked over the first stacking pair 17. In some embodiments, the first stacking pair 17 and the second stacking pair 18 are stacked in a B2B direction. The connecting unit 25 is interposed between the first stacking pair 17 and the second stacking pair 18. The bonded contact pads 250 of the connecting unit 25 may be referred to as intermediate connecting pads. The intermediate connecting pads are electrically coupled to the second interconnect structure 230 of the first stacking pair 17 and the second interconnect structure 230 of the second stacking pair 18.

In the semiconductor structures 101A, 101C, 201A and 201C of the present disclosure, the bonding between the two single wafers, such as the first wafer 10 and the second wafer 20 depicted in FIG. 3C or the third wafer 30 and the fourth wafer 40 depicted in FIG. 5B, is performed by the topmost metal layer formed in the BEOL structure in the interconnect structure (i.e. the first and second interconnect structures 130 and 230). There is no requirement to form extra bonding dielectric layer and extra bonding pads during the bonding process of two single wafers. Therefore, the process cost and complexity can be reduced. Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

1. A semiconductor device, comprising:
a first stacking pair and a connecting unit, wherein the first stacking pair comprises a first repeating unit and a second repeating unit,
the first repeating unit, comprising:
a first dielectric layer;
a first device surrounded by the first dielectric layer;
a first interconnect structure comprising a first metal layer over the first device, surrounded by the first dielectric layer, and electrically coupled to the first device,
the second repeating unit, comprising:
a second dielectric layer;
a second interconnect structure comprising a second metal layer bonded to the first metal layer;
a second device surrounded by the second dielectric layer and electrically coupled to the second metal layer,
the connecting unit comprising:
a contact pad electrically coupled to the first metal layer and the second metal layer.

2. The semiconductor device according to the claim 1, wherein the first metal layer comprises a first portion and a second portion separated from the first portion, the second metal layer comprises a first portion and a second portion separated from the first portion, the first portion of the first metal layer is electrically and directly connected to the first portion of the second metal layer, and the second portion of the first metal layer is electrically and directly connected to the second portion of the second metal layer.

3. The semiconductor device according to the claim 2, wherein the first device comprises a first capacitor structure comprising a first node and a second node, the second device comprises a second capacitor structure comprising a first node and a second node, the first node of the first capacitor structure is electrically coupled to the first node of the second capacitor structure, and the second node of the first capacitor structure is electrically coupled to the second node of the second capacitor structure.

4. The semiconductor device according to the claim 3, wherein the first nodes of the first capacitor structure and the second capacitor structure are electrically coupled to the first portions of the first metal layer and the second metal layer respectively, and the second nodes of the first capacitor structure and the second capacitor structure are electrically coupled to the second portions of the first metal layer and the second metal layer respectively.

5. The semiconductor device according to the claim 4, wherein the contact pad comprises:
a first contact pad electrically coupled to the first nodes of the first capacitor structure and the second capacitor structure, and
a second contact pad electrically coupled to the second nodes of the first capacitor structure and the second capacitor structure.

6. The semiconductor device according to the claim 5, wherein the first contact pad is configured to receive a first potential, and the second contact pad is configured to receive a second potential different from the first potential.

7. The semiconductor device according to the claim 2, wherein the first portion of the first metal layer comprises a first length, the second portion of the first metal layer comprises a second length, and the second length is different from the first length.

8. The semiconductor device according to the claim 3, wherein the first capacitor structure and the second capacitor structure are electrically connected in parallel.

9. The semiconductor device according to the claim 1, wherein the second interconnect structure further comprises a second through via electrically coupled to the second device, the second through via extends toward and electrically couples to the contact pad.

10. The semiconductor device according to the claim 9, further comprising a substrate below the first repeating unit and connected to the first dielectric layer, wherein the first interconnect structure further comprises a first through via extending toward and into the substrate.

11. The semiconductor device according to the claim 1, further comprising a second stacking pair disposed between the first stacking pair and the contact pad, wherein the second stacking pair comprises:
a third repeating unit proximal to the first stacking pair, comprising:
a third dielectric layer;
a third device surrounded by the third dielectric layer; and
a third interconnect structure comprising a third metal layer electrically coupled to the third device,
a fourth repeating unit distal to the first stacking pair, comprising:
a fourth dielectric layer;
a fourth interconnect structure comprising a fourth metal layer bonded to the third metal layer; and
a fourth device surrounded by the fourth dielectric layer and electrically coupled to the fourth metal layer,
wherein the first metal layer, the second metal layer, the third metal layer and the fourth metal layer are electrically coupled to the contact pad.

12. The semiconductor device according to the claim 11, wherein
the first device comprises a first capacitor structure comprising a first node and a second node,
the second device comprises a second capacitor structure comprising a first node and a second node,
the third device comprises a third capacitor structure comprising a first node and a second node,
the fourth device comprises a fourth capacitor structure comprising a first node and a second node,
the first nodes of the first capacitor structure, the second capacitor structure, the third capacitor structure and the fourth capacitor structure are electrically coupled together, and the second nodes of the first capacitor structure, the second capacitor structure, the third capacitor structure and the fourth capacitor structure are electrically coupled together.

13. The semiconductor device according to the claim 11, wherein the connecting unit further comprises an intermediate connecting pad formed between the first stacking pair and the second stacking pair, and the intermediate connecting pad is electrically connected to the second metal layer of the second repeating unit and the third metal layer of the third repeating unit.

14. The semiconductor device according to the claim 11, wherein the first repeating unit and the second repeating unit are stacked in a front-to-front direction, and the third repeating unit and the fourth repeating unit are stacked in a front-to-front direction, and the first stacking pair and the second stacking pair are stacked in a back-to-back direction.

15. A semiconductor device, comprising:
a substrate; and
N stacking pairs stacked to each other on the substrate, wherein each of the N stacking pairs comprises a first repeating unit and a second repeating unit, in each of the N stacking pairs,
the first repeating unit comprises a first capacitor structure including a first node, a second node and a first metal layer formed in a first interconnect structure,
the second repeating unit comprises a second capacitor structure including a first node, a second node and a second metal layer formed in a second interconnect structure,
the first nodes of the first capacitor structure and the second capacitor structure are electrically connected through bonding between the first metal layer and the second metal layer, and the second nodes of the first capacitor structure and the second capacitor structure are electrically connected through bonding between the first metal layer and the second metal layer, and
the N is an integer and ≥1.

16. The semiconductor device according to the claim 15, further comprising a connecting unit comprising a first contact pad and a second contact pad, wherein the first contact pad is electrically coupled to the first nodes of the first capacitor structure and the second capacitor structure in the N stacking pairs, and the second contact pad is electrically coupled to the second nodes of the first capacitor structure and the second capacitor structure in the N stacking pairs.

17. The semiconductor device according to the claim 16, wherein when N≥2, the connecting unit further comprises an intermediate connecting pad between two adjacent stacking pair of the N stacking pairs.

18. A method for manufacturing a semiconductor structure, comprising:
providing a first wafer including a first substrate, a first dielectric layer on the first substrate, a first device within the first dielectric layer, and a first metal layer over the first device and partially exposed through the first dielectric layer;
providing a second wafer including a second substrate, a second dielectric layer on the second substrate, a second device within the second dielectric layer, and a second metal layer over the second device and partially exposed through the second dielectric layer; and
bonding the second wafer to the first wafer, wherein the second wafer is disposed over the first wafer, the second metal layer is bonded to the first metal layer, and the second dielectric layer is bonded to the first dielectric layer.

19. The method according to the claim 18, wherein the second wafer includes a plurality of first conductive plugs between the second device and the second substrate before the bonding of the second wafer to the first wafer, and the removal of the second substrate includes at least partially exposing at least one of the plurality of first conductive plugs.

20. The method according to the claim 18, further comprising:
removing the second substrate until the second dielectric layer is exposed;
forming a first passivation layer on the second dielectric layer; and
forming a first pad disposed over the second device and at least partially exposed through the first passivation layer,
wherein the removal of the second substrate includes grinding, planarizing or etching the second substrate.
